(19) United States
(12) Patent Application Publication
(10) Pub. No.: US 2024/0396800 A1
(43) Pub. Date: Nov. 28, 2024

(54) SYSTEM AND METHOD FOR CONFIGURING A TENANT MANAGEMENT VIEW FOR A MULTI-TENANT DATA CENTER

(71) Applicant: Honeywell International Inc., Charlotte, NC (US)

(72) Inventors: Jayaprakash Meruva, Bangalore (IN); Jillee Yurembam, Bangalore (IN); Alpesh Saraiya, Bangalore (IN); Syed Jafar, Bangalore (IN)

(21) Appl. No.: 18/322,370

(22) Filed: May 23, 2023

(51) Int. Cl. H04L 41/085

(52) U.S. Cl. CPC H04L 41/085

(57) ABSTRACT

A computer-implemented method for configuring a tenant management view includes storing a tag template that is associated with a colocation tenant of a data center, the tag template includes a query for identifying in a data center management database one or more data center resources associated with the colocation tenant. The query is applied to the data center management database to identify the one or more data center resources associated with the colocation tenant. The identified one or more data center resources associated with the colocation tenant are tagged in the data center management database and report a value of one or more points associated with one or more of the data center resources is reported. The reported value of one or more of the points are displayed in the tenant management view.

### TECHNICAL FIELD

The present disclosure pertains generally to monitoring data centers and more particularly to systems and methods for configuring a tenant management view for a tenant of a multi-tenant data center.

### BACKGROUND

A data center typically includes a number of computer servers in close proximity to each other arranged in server racks. Some data servers are setup by a business to serve just that business. However, many data centers serve a number of different colocation tenants, each assigned to particular computer servers within the data center. A data center may be divided into a number of server racks, with each server rack having a number of computer servers. In some cases, each colocation tenant may be assigned to one or more server racks within the data center. A need remains for improved systems and methods for quickly and easily configuring a tenant management view that provides a particular colocation tenant of a multiple-tenant data center with data center information that is related to the particular colocation tenant without providing unwanted information that pertains to other colocation tenants of the multiple-tenant data center.

### SUMMARY

This disclosure relates generally to monitoring data centers and more particularly to systems and methods for configuring a tenant management view for a colocation tenant of a multi-tenant data center. An example may be found in a computer implemented method for configuring a tenant management view that displays one or more operating characteristics of one or more data center resources that are associated with a colocation tenant of a data center, the one or more data center resources of the data center managed through a data center management supervisor that references a data center management database. The method includes storing in a memory a tag template that is associated with the colocation tenant of the data center. The tag template includes a query for identifying in the data center management database one or more data center resources that are associated with the colocation tenant. One or more processors apply the query of the tag template to the data center management database to identify the one or more data center resources associated with the colocation tenant. The one or more processors tag the identified one or more data center resources that are associated with the colocation tenant in the data center management database and report a value of one or more points associated with one or more of the data center resources that are tagged in the data center management database. The method includes displaying the reported value of one or more of the points in the tenant management view created for the colocation tenant.

Another example may be found in a system for configuring a tenant management view that displays one or more operating characteristics of one or more data center resources that are associated with a colocation tenant of a data center. The system includes a data center management supervisor that references a data center management database. The data center management supervisor is configured to manage the one or more data center resources of the data center. The system includes a tenant management supervisor and a message broker, wherein the data center management supervisor and the tenant management supervisor communicate via the message broker. The tenant management supervisor is configured to receive user input that defines at least in part a tag template that is associated with the colocation tenant of the data center. The tag template includes a query for identifying one or more data center resources associated with the colocation tenant of the data center in the data center management database and to publish the tag template to the message broker. The data center management supervisor is configured to subscribe to and receive the tag template via the message broker and to apply the query of the tag template to the data center management database to identify the one or more data center resources associated with the colocation tenant of the data center. The data center management supervisor is configured to tag the identified one or more data center resources that are associated with the colocation tenant of the data center and to publish a value of one or more points associated with one or more of the tagged data center resources to the message broker. The tenant management supervisor is configured to subscribe to and receive the value of one or more points associated with one or more of the tagged data center resources via the message broker and to display on a display the published value of one or more of the points in the tenant management view of the colocation tenant.

Another example may be found in a computer implemented method for configuring a tenant management view that displays one or more operating characteristics of one or more data center resources that are associated with a colocation tenant of a data center. The one or more data center resources of the data center are managed through a data center management supervisor that references a data center management database. The method includes storing in a memory a tag template that is associated with the colocation tenant of the data center. The tag template identifies one or more data center resources associated with the colocation tenant of the data center. One or more processors identify the one or more data center resources associated with the colocation tenant of the data center in the data center management database and tag the identified one or more data center resources that are associated with the colocation tenant of the data center. The one or more processors report a value of one or more points associated with one or more of the tagged data center resources and display the reported value of one or more of the points in the tenant management view of the colocation tenant.

The preceding summary is provided to facilitate an understanding of some of the features of the present disclosure and is not intended to be a full description. A full appreciation of the disclosure can be gained by taking the entire specification, claims, drawings, and abstract as a whole.

### BRIEF DESCRIPTION OF THE DRAWINGS

The disclosure may be more completely understood in consideration of the following description of various illustrative embodiments of the disclosure in connection with the accompanying drawings, in which:

FIG. 1 is a schematic block diagram of an illustrative system;

FIGS. 2A and 2B are flow diagrams that together show an illustrative computer-implemented method for configuring a tenant management view for a colocation tenant of a data center;

FIGS. 3A and 3B are flow diagrams that together show an illustrative computer-implemented method for configuring a tenant management view for a colocation tenant of a data center;

FIG. 4 is a flow diagram showing an illustrative computer-implemented method for configuring a tenant management view for a colocation tenant of a data center;

FIG. 5 is a schematic block diagram showing an illustrative tenant management architecture;

FIG. 6 is a schematic block diagram showing an illustrative tenant management architecture; and

FIG. 7 is a schematic block diagram showing an illustrative onboarding workflow for a colocation tenant of a data center.

While the disclosure is amenable to various modifications and alternative forms, specifics thereof have been shown by way of example in the drawings and will be described in detail. It should be understood, however, that the intention is not to limit aspects of the disclosure to the particular illustrative embodiments described. On the contrary, the intention is to cover all modifications, equivalents, and alternatives falling within the spirit and scope of the disclosure.

### DESCRIPTION

The following description should be read with reference to the drawings wherein like reference numerals indicate like elements. The drawings, which are not necessarily to scale, are not intended to limit the scope of the disclosure. In some of the figures, elements not believed necessary to an understanding of relationships among illustrated components may have been omitted for clarity.

All numbers are herein assumed to be modified by the term “about”, unless the content clearly dictates otherwise. The recitation of numerical ranges by endpoints includes all numbers subsumed within that range (e.g., 1 to 5 includes 1, 1.5, 2, 2.75, 3, 3.80, 4, and 5).

As used in this specification and the appended claims, the singular forms “a”, “an”, and “the” include the plural referents unless the content clearly dictates otherwise. As used in this specification and the appended claims, the term “or” is generally employed in its sense including “and/or” unless the content clearly dictates otherwise.

It is noted that references in the specification to “an embodiment”, “some embodiments”, “other embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is contemplated that the feature, structure, or characteristic may be applied to other embodiments whether or not explicitly described unless clearly stated to the contrary.

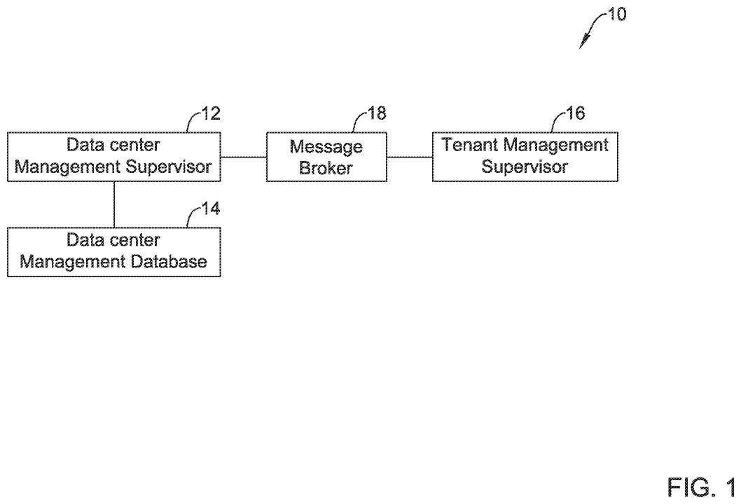

FIG. 1 is a schematic block diagram showing an illustrative system 10 for configuring a tenant management view that displays one or more operating characteristics of one or more data center resources that are associated with a colocation tenant of a data center. In some instances, the data center may include a plurality of colocation tenants each having one or more data center resources that are associated with the respective colocation tenant. The system 10 includes a data center management supervisor 12 that is configured to manage the one or more data center resources of the data center. The data center management supervisor 12 references a data center management database 14. The illustrative system 10 further includes a tenant management supervisor 16 and a message broker 18. In some instances, the data center management supervisor 12 and the tenant management supervisor 16 communicate via the message broker 18. In some instances, the message broker 18 may be an MQTT message broker, although other message brokers are contemplated.

To initially configuring the tenant management view for a particular colocation tenant of a data center, the tenant management supervisor 16 is configured to receive user input that defines at least in part a tag template for the particular colocation tenant. In some instances, the tag template includes a query for identifying one or more of the data center resources that are associated with the colocation tenant of the data center in the data center management database 14. In some instances, the data center resources include both data center resources and their respective points. In one example, the tenant management supervisor 16 is configured to publish the tag template to the message broker 18. The data center management supervisor 12 is configured to subscribe to and receive the tag template from the tenant management supervisor 16 via the message broker 18. The data center management supervisor 12 is configured to apply the query of the tag template to the data center management database 14 to identify the one or more data center resources associated with the colocation tenant and to tag the identified one or more data center resources that are associated with the colocation tenant. Subsequently, the data center management supervisor 12 is configured to publish a value of one or more points associated with one or more of the tagged data center resources to the message broker 18. In some cases, the data center management supervisor 12 is configured to repeatedly publish the value of one or more points associated with one or more of the tagged data center resources at predetermined intervals, upon a detected change in the value (COV), and/or at any other suitable time. In this example, the tenant management supervisor 16 is configured to subscribe to and receive the value of one or more points associated with one or more of the tagged data center resources via the message broker 18 as well as to display on a display the published value of one or more of the points in the tenant management view of the corresponding colocation tenant. In some instances, this may include publishing a model of tagged resources and points to the message broker 18.

In some instances, the tenant management supervisor 16 may be configured to receive user input that defines at least in part an updated tag template that is associated with the colocation tenant of the data center. The updated tag template may include an updated query for identifying one or more data center resources associated with the colocation tenant of the data center in the data center management database 14. The tenant management supervisor 16 may be configured to publish the updated tag template to the message broker 18. The data center management supervisor 12 may be configured to subscribe to and receive the updated tag template via the message broker and to apply the updated query of the updated tag template to the data center management database 14 to identify one or more updated data center resources associated with the colocation tenant of the data center. The data center management supervisor 12 may be configured to tag the identified one or more updated data center resources that are associated with the colocation tenant of the data center and to publish the value of one or more points associated with one or more of the tagged updated data center resources to the message broker 18. In some instances, this may include publishing a model of tagged resources and points to the message broker 18. The tenant management supervisor 16 may be configured to subscribe to and receive the value of one or more points associated with one or more of the tagged updated data center resources via the message broker 18 and to display on the display the published value of one or more of the points associated with one or more of the tagged updated data center resources in the tenant management view.

In some instances, the query of the tag template may include a plurality of queries for identifying the one or more data center resources associated with the colocation tenant of the data center. In some instances, the data center management supervisor 12 may be configured to publish a site registration to the message broker 18, wherein the site registration identifies the data center from a plurality of different data center sites. The tenant management supervisor 16 may be configured to subscribe and receive the site registration from the message broker 18 and to publish the tag template to the message broker 18 in response to receiving the site registration from the message broker 18. In some instances, the tenant management supervisor 16 may be configured to publish the tag template when the site registration from the message broker 18 corresponds to the data center that includes the one or more data resources associated with the colocation tenant.

In some instances, the tenant management supervisor may be configured to receive user input that defines at least in part a tag template for each of the plurality of colocation tenants of the data center. Each tag template may include a query for identifying one or more data center resources associated with the respective colocation tenant of the data center. In some instances, the data center management supervisor 12 may be configured to subscribe to and receive each tag template via the message broker 18, apply the query of each tag template to the data center management database 14 to identify the one or more data center resources associated with each of the respective colocation tenants of the data center, tag the identified one or more data center resources that are associated with each of the respective colocation tenant of the data center, and publish the value of one or more points associated with the one or more of the tagged data center resources associated with each of the respective colocation tenants to the message broker 18. In some instances, the model is published first. In some instances, the tenant management supervisor 16 may be configured to subscribe to and receive the value of one or more points associated with one or more of the tagged data center resources associated with each of the colocation tenants from the message broker 18 and to display a tenant management view for each of the colocation tenants, wherein the tenant management view includes the published value of one or more of the points associated with one or more of the tagged data center resources associated with the respective colocation tenant.

In some cases, rather than including a query, each tag template may provide a number of tag identifiers that identifies each of the one or more data center resources associated with the respective colocation tenant of the data center. The data center management supervisor 12 may be configured to subscribe to and receive each tag template via the message broker 18, use the tag identifiers of each tag template to identify the one or more data center resources associated with each of the respective colocation tenants of the data center, and publish the value of one or more points associated with the one or more of the tagged data center resources associated with each of the respective colocation tenants to the message broker 18. In some instances, the tenant management supervisor 16 may be configured to subscribe to and receive the value of one or more points associated with one or more of the tagged data center resources associated with each of the colocation tenants from the message broker 18 and to display a tenant management view for each of the colocation tenants, wherein the tenant management view includes the published value of one or more of the points associated with one or more of the tagged data center resources associated with the respective colocation tenant.

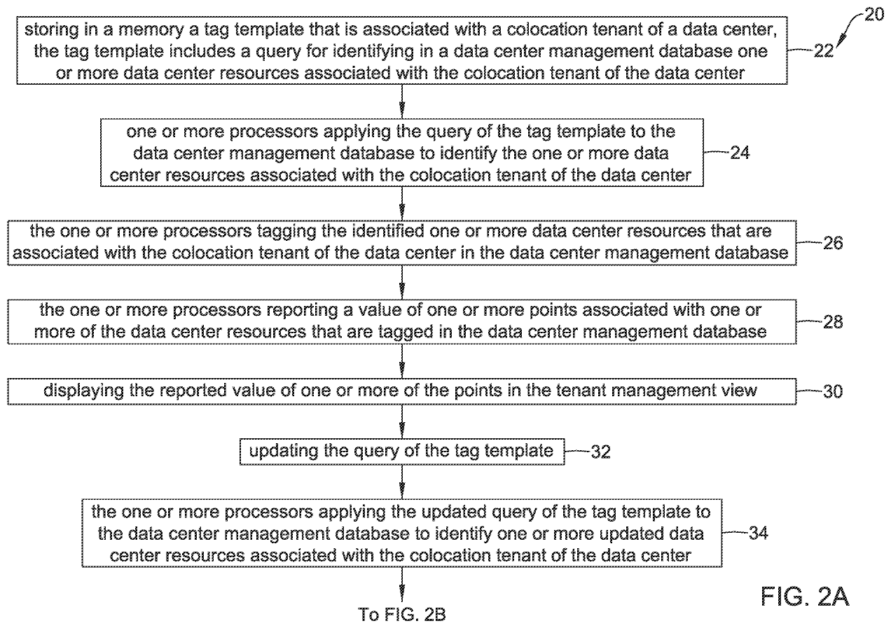

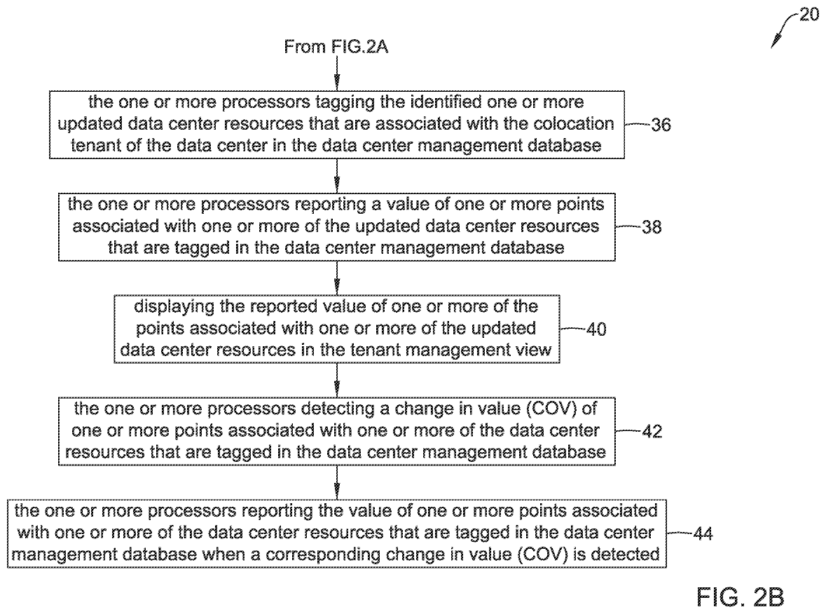

FIGS. 2A and 2B are flow diagrams that together show an illustrative computer-implemented method 20 for configuring a tenant management view that displays one or more operating characteristics of one or more data center resources that are associated with a particular colocation tenant of a data center. The one or more data center resources of the data center are managed through a data center management supervisor (such as the data center management supervisor 12) that references a data center management database (such as the data center management database 14). The illustrative method 20 includes storing in a memory a tag template that is associated with the colocation tenant of the data center. In some instances, the tag template includes a query for identifying in the data center management database 14 one or more data center resources associated with the colocation tenant of the data center, as indicated at block 22. In some instances, the query of the tag template may include a plurality of queries for identifying the one or more data center resources associated with the colocation tenant of the data center in the data center management database.

In this example method, one or more processors apply the query of the tag template to the data center management database to identify the one or more data center resources associated with the colocation tenant of the data center, as indicated at block 24. The one or more processors tag the identified one or more data center resources that are associated with the colocation tenant of the data center in the data center management database, as indicated at block 26. The one or more processors report a value of one or more points associated with one or more of the data center resources that are tagged in the data center management database, as indicated at block 28. The reported value of one or more of the points are displayed in the tenant management view of the corresponding colocation tenant of the data center, as indicated at block 30.

In some instances, the method 20 may further include updating the tag template, such as updating the query of the tag template, as indicated at block 32. In some instances, the one or more processors may apply the updated query of the tag template to the data center management database 14 to identify one or more updated data center resources associated with the colocation tenant of the data center, as indicated at block 34.

The method 20 continues in FIG. 2B, where the one or more processors may tag the identified one or more updated data center resources that are associated with the colocation tenant of the data center in the data center management database, as indicated at block 36. The one or more processors may report a value of one or more points associated with one or more of the updated data center resources that are tagged in the data center management database, as indicated at block 38. The reported value of one or more of the points associated with one or more of the updated data center resources may be displayed in the tenant management view of the corresponding colocation tenant of the data center, as indicated at block 40.

In some instances, the method 20 may include the one or more processors detecting a change in value (COV) of one or more points associated with one or more of the data center resources that are tagged in the data center management database, as indicated at block 42. The one or more processors may report the value of one or more points associated with one or more of the data center resources that are tagged in the data center management database when a corresponding change in value (COV) is detected, as indicated at block 44. The reported value of one or more of the points associated with one or more of the data center resources may be displayed in the tenant management view of the corresponding colocation tenant of the data center subsequent to the model being published.

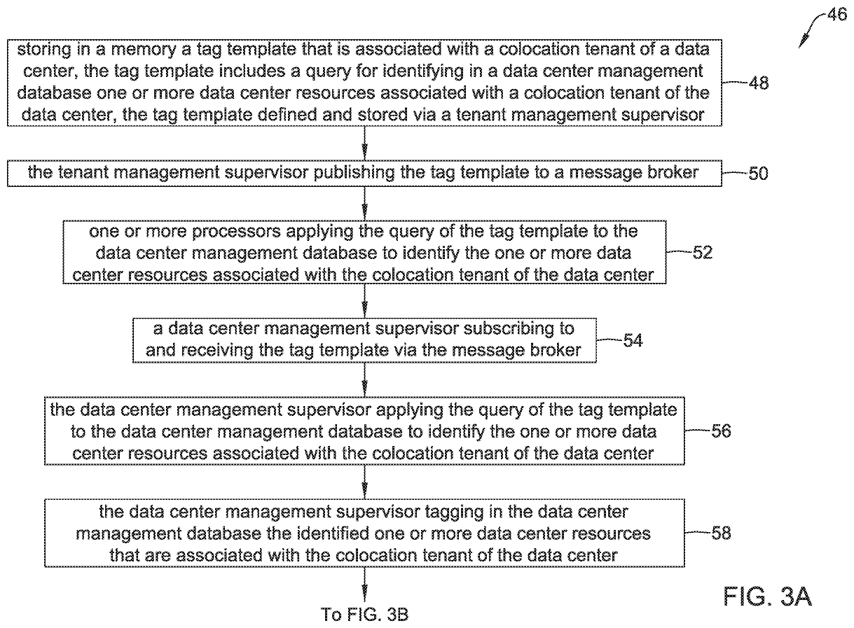

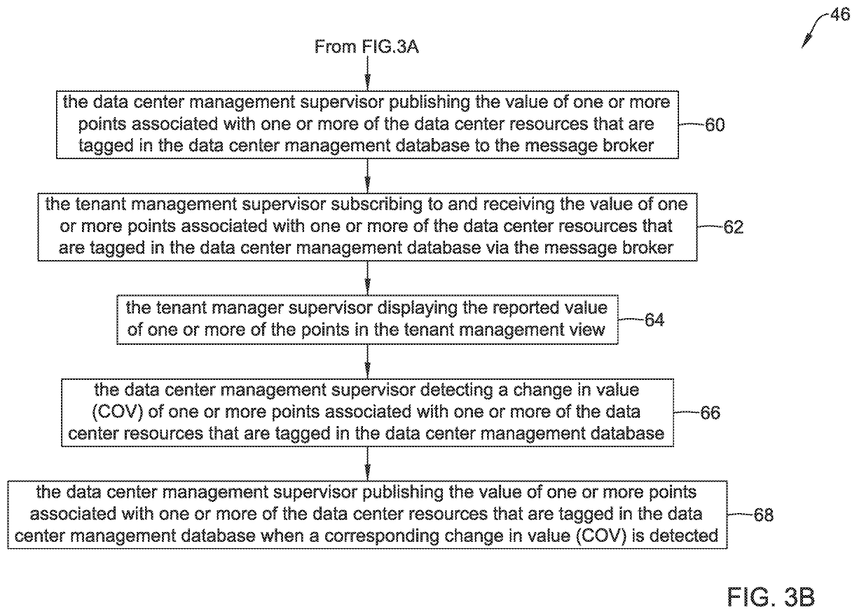

In some instances, the configuration of the tenant management view may be controlled through a tenant management supervisor. In some cases, the tag template is defined using the tenant management supervisor. The tenant management supervisor and the data center management supervisor may be operatively coupled via a message broker. FIGS. 3A and 3B are flow diagrams that together show an illustrative method 46 for configuring a tenant management view that displays one or more operating characteristics of one or more data center resources that are associated with a particular colocation tenant of a data center. In this example, the one or more data center resources of the data center are managed through a data center management supervisor (such as the data center management supervisor 12) that references a data center management database (such as the data center management database 14). The illustrative method 46 includes storing in a memory a tag template that is associated with the colocation tenant of the data center. In some cases, the tag template includes a query for identifying in the data center management database one or more data center resources associated with the colocation tenant of the data center. The tag template is defined and stored via the tenant management supervisor, as indicated at block 48. In some instances, the query of the tag template may include a plurality of queries for identifying the one or more data center resources associated with the particular colocation tenant of the data center.

In the example shown, the tenant management supervisor publishes the tag template to a message broker, as indicated at block 50. One or more processors apply the query of the tag template to the data center management database to identify the one or more data center resources associated with the colocation tenant of the data center, as indicated at block 52. A data center management supervisor subscribes to and receives the tag template from the tenant management supervisor via the message broker, as indicated at block 54. The data center management supervisor applies the query of the tag template to the data center management database in order to identify the one or more data center resources that are associated with the colocation tenant of the data center, as indicated at block 56. In some cases, the data center management supervisor tags in the data center management database the identified one or more data center resources that are associated with the particular colocation tenant of the data center, as indicated at block 58.

The data center management supervisor publishes the value of one or more points associated with one or more of the data center resources that are tagged in the data center management database, as indicated at block 60. The tenant management supervisor subscribes to and receives the value of one or more points associated with the one or more of the data center resources that are tagged in the data center management database via the message broker, as indicated at block 62. The tenant management supervisor displays the reported value of one or more of the points in the tenant management view of the particular colocation tenant of the data center, as indicated at block 64. In some cases, the data center management supervisor monitors and detects a change in value (COV) of one or more points associated with one or more of the data center resources that are tagged in the data center management database, as indicated at block 66. The data center management supervisor publishes the updated value of one or more points associated with one or more of the data center resources that are tagged in the data center management database when a corresponding change in value (COV) is detected, as indicated at block 68. The tenant management supervisor receives the updated value of one or more points associated with the one or more of the data center resources that are tagged in the data center management database via the message broker, and displays the updated value of one or more of the points in the tenant management view of the particular colocation tenant of the data center.

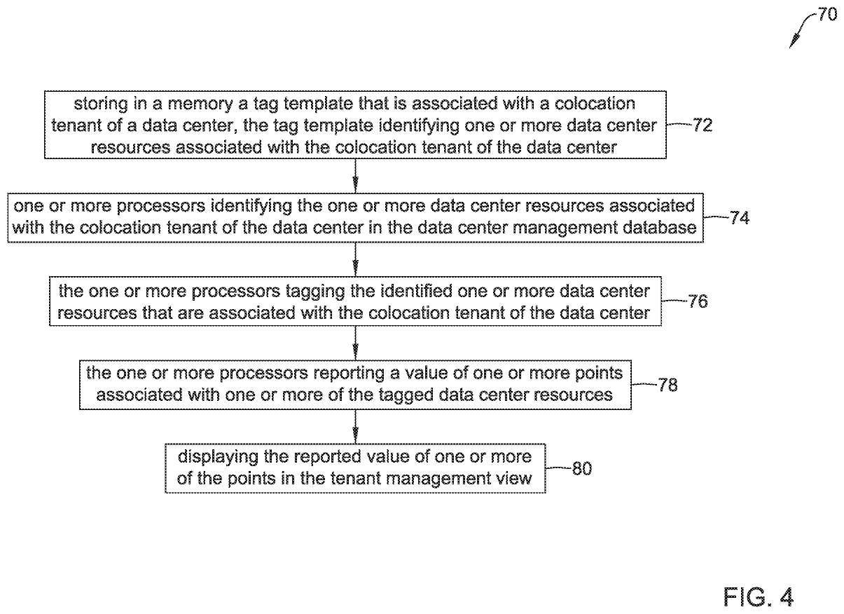

FIG. 4 is a flow diagram showing an illustrative computer-implemented method 70 for configuring a tenant management view that displays one or more operating characteristics of one or more data center resources that are associated with a particular colocation tenant of a data center. In this example, the one or more data center resources of the data center are managed through a data center management supervisor (such as the data center management supervisor 12) that references a data center management database (such as the data center management database 14). The illustrative method 70 includes storing in a memory a tag template that is associated with the particular colocation tenant of the data center. The tag template identifies one or more data center resources associated with the colocation tenant of the data center, as indicated at block 72. One or more processors identify the one or more data center resources associated with the colocation tenant of the data center in the data center management database, as indicated at block 74. The one or more processors tag the identified one or more data center resources that are associated with the particular colocation tenant of the data center, as indicated at block 76. The one or more processors report a value of one or more points associated with one or more of the tagged data center resources, as indicated at block 78. The reported value of one or more of the points are displayed in the tenant management view of the particular colocation tenant of the data center, as indicated at block 80.

In some instances, the tenant management view may be controlled by a tenant management supervisor (such as the tenant management supervisor 16) and the tenant management supervisor and the data center management supervisor may be operatively coupled via a message broker (such as the message broker 18). In some instances, the tag template may be defined and stored via the tenant management supervisor, and the tenant management supervisor may publish the tag template to the message broker. In some instances, the data center management supervisor subscribes to and receives the tag template via the message broker, and may identify the one or more data center resources associated with the particular colocation tenant in the data center management database. In some instances, the data center management supervisor may tag the identified one or more data center resources that are associated with the colocation tenant. The data center management supervisor may publish the value of one or more points associated with one or more of the data center resources to the message broker. The tenant management supervisor may subscribe to and receive the value of one or more points associated with one or more of the tagged data center resources via the message broker, and may display the published value of one or more of the points in the tenant management view of the particular colocation tenant of the data center.

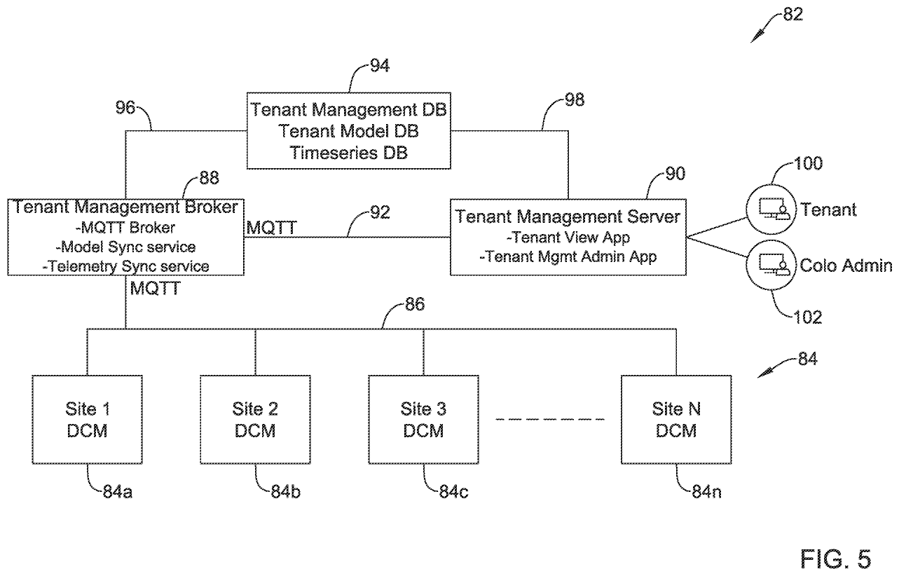

FIG. 5 is a schematic block diagram showing an illustrative tenant management architecture 82. The illustrative architecture 82 includes a number of Site DCM (data center managers) 84, individually labeled as 84a, 84b, 84c and through 84n. Each of the Site DCMs 84 may be considered as being assigned to a particular data center site. Each data center site includes a number of server racks each including a number of computer servers. Each data center site also includes support equipment such as cooling equipment. Each of the Site DCMs 84 communicate via a network 86 with a tenant management broker 88. The network 86 may represent any of a variety of different network types. In some instances, the network 86 may generically represent the Internet. In some instances, the tenant management broker 88 is an MQTT broker. The tenant management broker 88 communicates with a tenant management server 90 via a network 92 and also communicates with a tenant management database 94 via a network 96. The tenant management server 90 may also communicate with the tenant management database 94 via a network 98. As shown, each tenant 100 and each colocation administrator may log into the tenant management server 90 via a https connection.

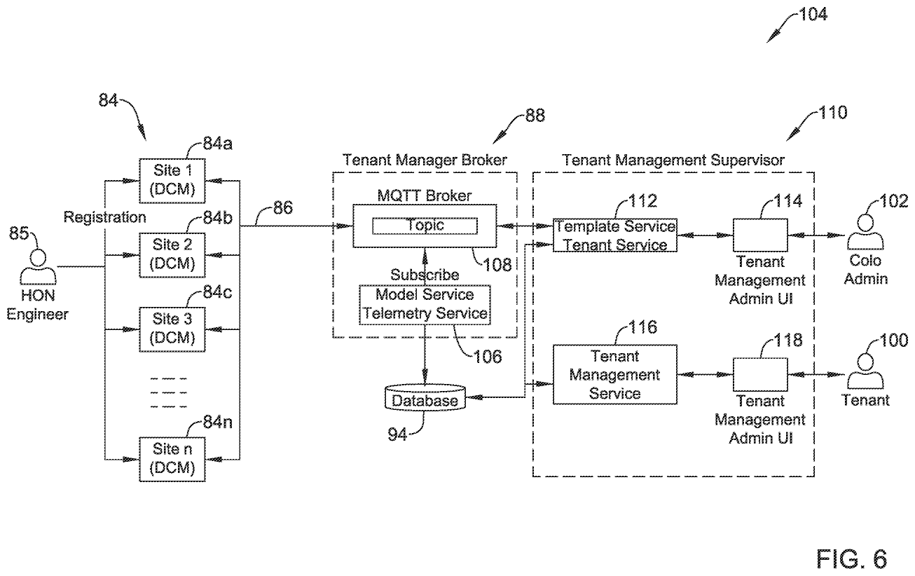

FIG. 6 is a schematic block diagram showing an illustrative tenant management architecture 104. The illustrative architecture 104 includes the number of Site DCMs (data center managers) 84, individually labeled as 84a, 84b, 84c and through 84n. In some instances, an engineer 85 provides information to the Site DCMs 84. The tenant manager broker 88 communicates with the Site DCMs 84 via a network 86. The Site DCMs 84 may publish information to the tenant manager broker 88. In some instances, as shown, the tenant manager broker 88 may include a Model Service Telemetry Service block 106 that communicates with the tenant management database 94, and may itself subscribe to TOPICS 108 within the tenant management broker 88.

The architecture 104 includes a tenant management supervisor 110. In some instances, the tenant management supervisor 110 may be considered as being an example of, or including, the tenant management server 90 shown in FIG. 5. The tenant management supervisor 110 includes a Template Service and Tenant Service block 112 that communicates with the TOPICS 108 and the tenant management database 94, and also communicates with a Tenant Management Admin UI (User interface) 114. The colocation administrator 102 communicates with the Tenant Management Admin UI 114. The tenant management supervisor 110 also includes a Tenant Management Service block 116 that itself communicates with a Tenant Management web 118. The tenants 100 communicate with the Tenant Management web 118.

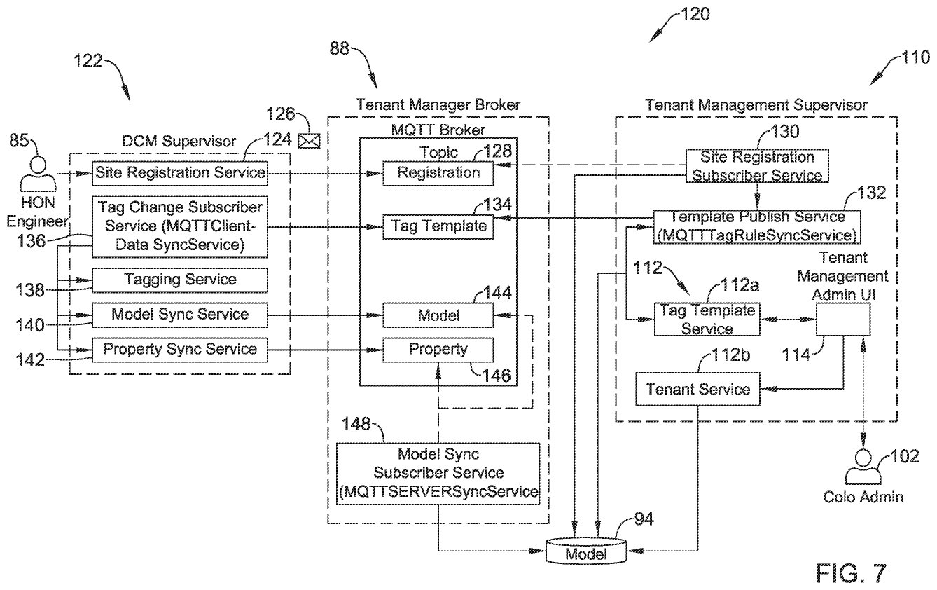

FIG. 7 is a schematic block diagram showing an illustrative onboarding workflow 120 for a colocation tenant of a data center. The illustrative onboarding workflow 120 shows how information flows between a Data Center Management (DCM) Supervisor 122, the tenant manager broker 88 and the Tenant Management Supervisor 110. The DCM Supervisor 122 includes a Site Registration Service 124, which receives information from the engineer 85. The Site Registration Service 124 allows for setting up an MQTT broker connection. Once the Site Registration Service 124 successfully connects to the Tenant Management Broker 88, and upon saving the configuration, the site detail will be published to the Tenant Management Broker 88, as represented by an envelope 126. In some instances, the published information as represented by the envelope 126 may include a Site Name and a Unique Site Identifier. The Tenant Management Broker 88 includes a Registration block 128 that represents one of the topics under the TOPICS 108 umbrella (FIG. 6).

The Tenant Management Supervisor 110 includes a Site Registration Subscriber Service 130 that subscribes to the site registration via the Registration block 128. The Site Registration Subscriber Service 130 allows for setting up the MQTT broker connection, subscribing to the Site Registration Topic, getting site details, and persisting a model database. Whenever a new site is received, the Site Registration Subscriber Service 130 evokes a Template Publish Service block 132, which is a service that reads tag templates from the database and publishes the tag templates. The Template Publish Service Block 132 communicates with a Tag Template block 134 that is part of the Tenant Management Broker 88. In some instances, publishing the Tag Template includes a tag rule that is used to identify the devices and point data from a site. As an example, this may include TagName, which is the name of the tag, Tags, which are the applicable devices that need to be tagged, and BqlQueries, which are the BWL queries that are used to search the devices. In one example, to tag all racks of the data center, the Tag Template may take the form of:

```
{
  “tagName”: “rack”,
  “bqlQueries”: [
    “station:|slot:/Drivers|bql:select ordInSession from
  baja:Component where (displayName like ‘RACK-%’)”],
  “tags”: [
    {
    “defaultValue”: “Element”,
    “id”: “us:entityClass”,
    “type”: “String”
    },
    {
    “defaultValue”: “Equipment”,
    “id”: “us:entityType”,
    “type”: “String”
    }
  ]
}
```

The DCM Supervisor 122 includes a Tag Change Subscriber Service block 136, which is a service that allows subscribing to a tag template and saving locally. If a previous tag template is found, they are compared to find any changes in the tag template. If any changes are found (including the creation of a new tag template), a Tag Change Event is raised. The TAG Change Subscriber Service block 136 subscribes to the Tag Template block 134. The DCM Supervisor 122 includes a Tagging Service block 138, which listens to Tag Change Events, scans the data center management database and tags the one or more data center resources and points by applying a Tag Rule. The Tag Rule may implement the query expressed in the tag template. Once complete, a Tagging Completed Event is raised. The DCM Supervisor 122 includes a Model Sync Service block 140, which listens to the Tagging Completed Event and uses the Tag Template to get the Tagged elements and points and generates a model. The Model sync Service block 140 publishes the model for the particular colocation tenant to a Model block 144 within the Tenant Management Broker 88. The DCM Supervisor 122 includes a Property Sync Service block 142 that listens for COV events for a point and publishes the value to the Tenant Management Broker 88 for display on the tenant management view of the particular colocation tenant of the data center.

The Tenant Management Broker 88 includes a Property block 146 that subscribes to the Model block 144 in order to obtain updated information from the model. The Tenant Management Broker 88 also includes a Model Sync Subscriber Service block 148 that allows for subscribing to the model topics and saving to the database 94. Publishing the model includes publishing the tagged devices and points from the published model 144. This may include a SiteID, which is a site unique identifier, a Name, which is the name of the device, and one or more PropertyEntities, which may be a list of points associated with the device. Publishing Property Details includes publishing a change of value for a point. This may include a LastUpdated value, which is the date and time the data was recorded, a Points listing, which is a listing of points data, an ID value, which is the point unique site identifier, and a Value, which is the value for that point at that time.

The Tenant Management Supervisor 110 includes both a Tag Template Service block 112a and a Tenant Service block 112b. The colocation admin 102 may initially configure a new colocation tenant via the tenant service block 112b and create and/or update a colocation tenant entry in the database 94. The colocation admin 102 may also configure (e.g. create and/or update) the tag template for the particular colocation tenant via the tag template service 112a. Once configured, the tag template service 112a may provide the tag template to the template publish service 132, which may publish the tag template to the tenant manager broker 88 as described above.

The following table provides an illustrative listing of available tags that may be referenced in the tag template and/or used to identify and tag points in the data center management database 14. The illustrative listing includes a listing of points, a listing of corresponding equipment types and corresponding tags that correspond to the particular point and the particular equipment types. These tags may be referenced in the tag template (e.g. in the blqquery) and/or used to identify and tag points in the data center management database.

| | Equipment | |
|---|---|---|
| Required Points | Type | Tags |
| Rack Name | Rack | hon:rackName (marker tag) |
| Rack Cold Aisle | Rack -> rPDU | hon:rack (marker tag) |
| Temperature TOP | | hon:pdu (marker tag) |
| | | hon:coldAisle (marker tag) |
| | | hs:temp (marker tag) |
| | | hon:position = “Top” |
| | | (string tag) |
| Rack Cold Aisle | Rack -> rPDU | hon:rack (marker tag) |
| Temperature Middle | | hon:pdu (marker tag) |
| | | hon:coldAisle (marker tag) |
| | | hs:temp (marker tag) |
| | | hon:position = “Middle” |
| | | (string tag) |
| Rack Cold Aisle | Rack -> rPDU | hon:rack (marker tag) |
| Temperature Bottom | | hon:pdu (marker tag) |
| | | hon:coldAisle (marker tag) |
| | | hs:temp (marker tag) |
| | | hon:position = “Bottom” |
| | | (string tag) |
| Rack Cold Aisle | Rack -> rPDU | hon:rack (marker tag) |
| Temperature Average | | hon:pdu (marker tag) |
| | | hon:coldAisle (marker tag) |
| | | hs:temp (marker tag) |
| | | hon:avg (marker tag) |
| Rack Hot Aisle | Rack -> rPDU | hon:hotAisle (marker tag) |
| Temperature TOP | | hs:temp (marker tag) |
| | | hon:position = “Top” |
| | | (string tag) |
| Rack Hot Aisle | Rack -> rPDU | hon:hotAisle (marker tag) |
| Temperature Middle | | hs:temp (marker tag) |
| | | hon:position = “Middle” |
| | | (string tag) |
| Rack Hot Aisle | Rack -> rPDU | hon:hotAisle (marker tag) |
| Temperature Bottom | | hs:temp (marker tag) |
| | | hon:position = “Bottom” |
| | | (string tag) |
| Rack Hot Aisle | Rack -> rPDU | hon:rack (marker tag) |
| Temperature Average | | hon:hotAisle (marker tag) |
| | | hs:temp (marker tag) |
| | | hon:avg |
| Rack Relative | Rack -> rPDU | hon:rack (marker tag) |
| Humidity | | hon:pdu (marker tag) |
| | | hs:humidity (marker tag) |
| | | hs:avg (marker tag) |
| RackIntakeDewPoint | Rack -> rPDU | hon:rack (marker tag) |
| | | hs:dew (marker tag) |
| | | hs:temp (marker tag) |
| Rack Active Power | Rack -> rPDU | hon:rack (marker tag) |
| | | hon:pdu (marker tag) |
| | | hs:power (marker tag) |
| rPDU Active Energy | Rack -> rPDU | hon:rack (marker tag) |
| | | hon:pdu (marker tag) |
| | | hs:energy (marker tag) |
| | | hs:hisTotalized (marker tag) |
| Rack Power Capacity | Rack | hon:rack (marker tag) |
| | | hon:capacity (marker tag) |
| Rack Active Power | Rack | hon:rack (marker tag) |
| | | hs:power (marker tag) |
| | | hs:active (marker tag) |
| Rack Power | Rack | hon:rack (marker tag) |
| Utilization | | hs:power (marker tag) |
| | | hon:percentage (marker tag) |
| Rack Power Surge | Rack | hon:rack (marker tag) |
| | | hs:power (marker tag) |
| | | hon:surge (marker tag) |
| Rack Space Total | Rack | hon:rack (marker tag) |
| | | hon:ru (marker tag) |
| | | hon:capacity (marker tag) |
| | | hs:total (marker tag) |
| | | hon:position = “Front” |
| | | (String tag) |
| Rack Space Total | Rack | hon:rack (marker tag) |
| Capacity Rear | | hon:ru (marker tag) |
| | | hon:capacity (marker tag) |
| | | hs:total (marker tag) |
| | | hon:position = “Rear” |
| | | (String tag) |
| Rack Space Used | Rack | hon:rack (marker tag) |
| Capacity Front | | hon:ru (marker tag) |
| | | hs:occupied |
| | | hon:position = “Front” |
| | | (String tag) |
| Rack Space Util front | Rack | hon:rack (marker tag) |
| | | hon:ru (marker tag) |
| | | hon:space (marker tag) |
| | | hon:position = “Front” |
| | | (String tag) |
| Rack Space Free Front | Rack | hon:ru (marker tag) |
| | | hon:position = “Front” |
| | | (String tag) |
| Rack Space Free Front | Rack | hon:rack (marker tag) |
| Percentage | | hon:ru (marker tag) |
| | | hon:percentage (marker tag) |
| | | hon:position = “Front” |
| | | (String tag) |
| Rack Contigous Space | Rack | hon:rack (marker tag) |
| Available Front | | hon:ru (marker tag) |
| | | hs:max (marker tag) |
| | | hon:position = “Front” |
| | | (String tag) |
| Rack Space Used | Rack | hon:rack (marker tag) |
| Capacity Rear | | hon:ru (marker tag) |
| | | hs:occupied (marker tag) |
| | | hon:position = “Rear” |
| | | (String tag) |
| Rack Space Used | Rack | hon:rack (marker tag) |
| Capacity Rear | | hon:ru (marker tag) |
| | | hs:space (marker tag) |
| | | hon:position = “Rear” |
| | | (String tag) |
| Rack Space Free | Rack | hon:ru (marker tag) |
| Rear | | hon:position = “Rear” |
| | | (String tag) |
| Rack Space Free | Rack | hon:rack (marker tag) |
| Front Percentage | | hon:ru (marker tag) |
| | | hs:percentage (marker tag) |
| | | hon:position = “Rear” |
| | | (String tag) |
| Rack Contiguous | Rack | hon:rack (marker tag) |
| Space Available Front | | hon:ru (marker tag) |
| | | hs:max (marker tag) |
| | | hon:position = “Rear” |
| | | (String tag) |

Those skilled in the art will recognize that the present disclosure may be manifested in a variety of forms other than the specific embodiments described and contemplated herein. Accordingly, departure in form and detail may be made without departing from the scope and spirit of the present disclosure as described in the appended claims.

What is claimed is:

1. A computer implemented method for configuring a tenant management view that displays one or more operating characteristics of one or more data center resources that are associated with a colocation tenant of a data center, the one or more data center resources of the data center managed through a data center management supervisor that references a data center management database, the method comprising:
storing in a memory a tag template that is associated with the colocation tenant of the data center, the tag template includes a query for identifying in the data center management database one or more data center resources associated with the colocation tenant of the data center;
one or more processors applying the query of the tag template to the data center management database to identify the one or more data center resources associated with the colocation tenant of the data center;
the one or more processors tagging the identified one or more data center resources that are associated with the colocation tenant of the data center in the data center management database;
the one or more processors reporting a value of one or more points associated with one or more of the data center resources that are tagged in the data center management database; and
displaying the reported value of one or more of the points in the tenant management view.

2. The method of claim 1, further comprising:
updating the query of the tag template;
the one or more processors applying the updated query of the tag template to the data center management database to identify one or more updated data center resources associated with the colocation tenant of the data center;
the one or more processors tagging the identified one or more updated data center resources that are associated with the colocation tenant of the data center in the data center management database;
the one or more processors reporting a value of one or more points associated with one or more of the updated data center resources that are tagged in the data center management database; and
displaying the reported value of one or more of the points associated with one or more of the updated data center resources in the tenant management view.

3. The method of claim 1, further comprising:
the one or more processors detecting a change in value (COV) of one or more points associated with one or more of the data center resources that are tagged in the data center management database; and
the one or more processors reporting the value of one or more points associated with one or more of the data center resources that are tagged in the data center management database when a corresponding change in value (COV) is detected.

4. The method of claim 1, wherein the query of the tag template includes a plurality of queries for identifying the one or more data center resources associated with the colocation tenant of the data center in the data center management database.

5. The method of claim 1, wherein the tenant management view is controlled by a tenant management supervisor, wherein the tag template is defined using the tenant management supervisor.

6. The method of claim 5, wherein the tenant management supervisor and the data center management supervisor are operatively coupled via a message broker.

7. The method of claim 6, wherein:
the tag template is defined and stored via the tenant management supervisor;
the tenant management supervisor publishing the tag template to the message broker;
the data center management supervisor subscribing to and receiving the tag template via the message broker;
the data center management supervisor applying the query of the tag template to the data center management database to identify the one or more data center resources associated with the colocation tenant of the data center;
the data center management supervisor tagging in the data center management database the identified one or more data center resources that are associated with the colocation tenant of the data center;
the data center management supervisor publishing the value of one or more points associated with one or more of the data center resources that are tagged in the data center management database to the message broker;
the tenant management supervisor subscribing to and receiving the value of one or more points associated with one or more of the data center resources that are tagged in the data center management database via the message broker; and
the tenant management supervisor displaying the published value of one or more of the points in the tenant management view.

8. The method of claim 7, further comprising:
the data center management supervisor detecting a change in value (COV) of one or more points associated with one or more of the data center resources that are tagged in the data center management database; and
the data center management supervisor publishing the value of one or more points associated with one or more of the data center resources that are tagged in the data center management database when a corresponding change in value (COV) is detected.

9. A system for configuring a tenant management view that displays one or more operating characteristics of one or more data center resources that are associated with a colocation tenant of a data center, the system comprising:
a data center management supervisor that references a data center management database, the data center management supervisor is configured to manage the one or more data center resources of the data center;
a tenant management supervisor;
a message broker, wherein the data center management supervisor and the tenant management supervisor communicate via the message broker;
the tenant management supervisor is configured to receive user input that defines at least in part a tag template that is associated with the colocation tenant of the data center, the tag template includes a query for identifying one or more data center resources associated with the colocation tenant of the data center in the data center management database;
the tenant management supervisor is configured to publish the tag template to the message broker;
the data center management supervisor is configured to subscribe to and receive the tag template via the message broker;
the data center management supervisor is configured to apply the query of the tag template to the data center management database to identify the one or more data center resources associated with the colocation tenant of the data center;
the data center management supervisor is configured to tag the identified one or more data center resources that are associated with the colocation tenant of the data center;
the data center management supervisor is configured to publish a value of one or more points associated with one or more of the tagged data center resources to the message broker;
the tenant management supervisor is configured to subscribe to and receive the value of one or more points associated with one or more of the tagged data center resources via the message broker; and
the tenant management supervisor is configured to display on a display the published value of one or more of the points in the tenant management view.

10. The system of claim 9, further comprising:
the data center management supervisor is configured to detect a change in value (COV) of one or more points associated with one or more of the tagged data center resources; and
the data center management supervisor is configured to publish the value of one or more points associated with one or more of the tagged data center resources when a corresponding change in value (COV) is detected.

11. The system of claim 9, wherein:
the tenant management supervisor configured to receive user input that defines at least in part an updated tag template that is associated with the colocation tenant of the data center, the updated tag template includes an updated query for identifying one or more data center resources associated with the colocation tenant of the data center in the data center management database;
the tenant management supervisor is configured to publish the updated tag template to the message broker;
the data center management supervisor is configured to subscribe to and receive the updated tag template via the message broker;
the data center management supervisor is configured to apply the updated query of the updated tag template to the data center management database to identify one or more updated data center resources associated with the colocation tenant of the data center;
the data center management supervisor is configured to tag the identified one or more updated data center resources that are associated with the colocation tenant of the data center;
the data center management supervisor is configured to publish the value of one or more points associated with one or more of the tagged updated data center resources to the message broker;
the tenant management supervisor is configured to subscribe to and receive the value of one or more points associated with one or more of the tagged updated data center resources via the message broker; and
the tenant management supervisor is configured to display on the display the published value of one or more of the points associated with one or more of the tagged updated data center resources in the tenant management view.

12. The system of claim 9, wherein the query of the tag template includes a plurality of queries for identifying the one or more data center resources associated with the colocation tenant of the data center.

13. The system of claim 9, wherein:
the data center management supervisor is configured to publish a site registration to the message broker, wherein the site registration identifies the data center from a plurality of data centers;
the tenant management supervisor is configured to subscribe and receive the site registration from the message broker; and
the tenant management supervisor is configured to publish the tag template to the message broker in response to receiving the site registration from the message broker.

14. The system of claim 13, wherein the tenant management supervisor is configured to publish the tag template when the site registration from the message broker corresponds to the data center that includes the one or more data resources associated with the colocation tenant.

15. The system of claim 9, wherein the data center includes a plurality of colocation tenants each having one or more data center resources that are associated with the respective colocation tenant.

16. The system of claim 15, wherein the tenant management supervisor is configured to receive user input that defines at least in part a tag template for each of the plurality of colocation tenants of the data center, each tag template includes a query for identifying one or more data center resources associated with the respective colocation tenant of the data center.

17. The system of claim 16, wherein the data center management supervisor is configured to:
subscribe to and receive each tag template via the message broker;
apply the query of each tag template to the data center management database to identify the one or more data center resources associated with each of the respective colocation tenants of the data center;
tag the identified one or more data center resources that are associated with each of the respective colocation tenant of the data center; and
publish the value of one or more points associated with the one or more of the tagged data center resources associated with each of the respective colocation tenants to the message broker.

18. The system of claim 17, wherein the tenant management supervisor is configured to:
subscribe to and receive the value of one or more points associated with one or more of the tagged data center resources associated with each of the colocation tenants to the message broker via the message broker; and
the tenant management supervisor is configured to display a tenant management view for each of the colocation tenants, wherein the tenant management view includes the published value of one or more of the points associated with one or more of the tagged data center resources associated with the respective colocation tenant.

19. A computer implemented method for configuring a tenant management view that displays one or more operating characteristics of one or more data center resources that are associated with a colocation tenant of a data center, the one or more data center resources of the data center managed through a data center management supervisor that references a data center management database, the method comprising:
storing in a memory a tag template that is associated with the colocation tenant of the data center, the tag template identifying one or more data center resources associated with the colocation tenant of the data center;
one or more processors identify the one or more data center resources associated with the colocation tenant of the data center in the data center management database;
the one or more processors tagging the identified one or more data center resources that are associated with the colocation tenant of the data center;
the one or more processors reporting a value of one or more points associated with one or more of the tagged data center resources; and
displaying the reported value of one or more of the points in the tenant management view.

20. The method of claim 19, wherein the tenant management view is controlled by a tenant management supervisor and the tenant management supervisor and the data center management supervisor are operatively coupled via a message broker, and wherein:
the tag template is defined and stored via the tenant management supervisor;
the tenant management supervisor publishing the tag template to the message broker;
the data center management supervisor subscribing to and receiving the tag template via the message broker;
the data center management supervisor identifying the one or more data center resources associated with the colocation tenant in the data center management database;
the data center management supervisor tagging the identified one or more data center resources that are associated with the colocation tenant;
the data center management supervisor publishing the value of one or more points associated with one or more of the data center resources to the message broker;
the tenant management supervisor subscribing to and receiving the value of one or more points associated with one or more of the tagged data center resources via the message broker; and
the tenant management supervisor displaying the published value of one or more of the points in the tenant management view.
